(19) United States
(12) Patent Application Publication
(10) Pub. No.: US 2024/0152671 A1
(43) Pub. Date: May 9, 2024

(54) VIOLATION CHECKING METHOD BY MACHINE LEARNING BASED CLASSIFIER

(71) Applicant: MEDIATEK INC., Hsin-chu (TW)

(72) Inventors: Chi-Ming Lee, Hsinchu City (TW); Chung-An Wang, Hsinchu City (TW); Cheok Yan Goh, Hsinchu City (TW); Chia-Cheng Tsai, Hsinchu City (TW); Chien-Hsin Yeh, Hsinchu City (TW); Chia-Shun Yeh, Hsinchu City (TW); Chin-Tang Lai, Hsinchu City (TW)

(73) Assignee: MEDIATEK INC., Hsin-Chu (TW)

(21) Appl. No.: 18/501,044

(22) Filed: Nov. 3, 2023

Related U.S. Application Data
(60) Provisional application No. 63/382,306, filed on Nov. 4, 2022.

(51) Int. Cl. G06F 30/27

(52) U.S. Cl. CPC G06F 30/27

(57) ABSTRACT

A violation checking method includes generating a violation log report for a design, classifying violation logs in the violation log report into high-risk logs and low-risk logs by a machine learning model, reviewing the high-risk logs, and modifying the design if at least one bug is identified in the high-risk logs.

### CROSS REFERENCE TO RELATED APPLICATIONS

This application claims the benefit of U.S. Provisional Application No. 63/382,306, filed on Nov. 4, 2022. The content of the application is incorporated herein by reference.

### BACKGROUND

Violation check process for design verification involves iterative simulations to ensure correct functionality and behavior of a design before the design tapes out. In each simulation iteration, the violations are outputted to flag suspicious conditions. Designers need to manually review the violations which are either waivable violations (false alarms) or true design issues that must be fixed.

The review process requires cross team expertise of design domain knowledge and lots of time to investigate violations. As the complexity of the design increases, the overwhelming workload during the time limited violation review process may jeopardize the correction for the register transfer level (RTL) code and induce engineering change order (ECO) after register transfer level (RTL) freezes.

The consumption time for fixing bugs after register transfer level (RTL) freezes is much longer than the consumption time for fixing bugs before register transfer level (RTL) freezes. Therefore, the review order in review process is critical for designers. The high-risk violation logs should be reviewed first, and the low-risk violation logs can be reviewed later. A tool to decide whether the violation logs are high-risk or low-risk is desirable.

### SUMMARY

An embodiment provides a violation checking method including generating a violation log report for a design, classifying violation logs in the violation log report into high-risk logs and low-risk logs by a machine learning model, reviewing the high-risk logs, and modifying the design if at least one bug is identified in the high-risk logs.

Another embodiment provides a violation checking method including generating a violation log report for a design, classifying violation logs in the violation log report into high-risk logs and low-risk logs by a machine learning model, reviewing the high-risk logs, after reviewing the high-risk logs, reviewing the low-risk logs, and modifying the design if at least one bug is identified in the low-risk logs.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a flowchart of a violation checking method using a machine learning model according to an embodiment of the present invention.

FIG. 2 is an architecture of a violation checking method using a machine learning model according to an embodiment of the present invention.

FIG. 3 is a flowchart of a machine learning method used in the violation checking method in FIG. 1 according to an embodiment of the present invention.

### DETAILED DESCRIPTION

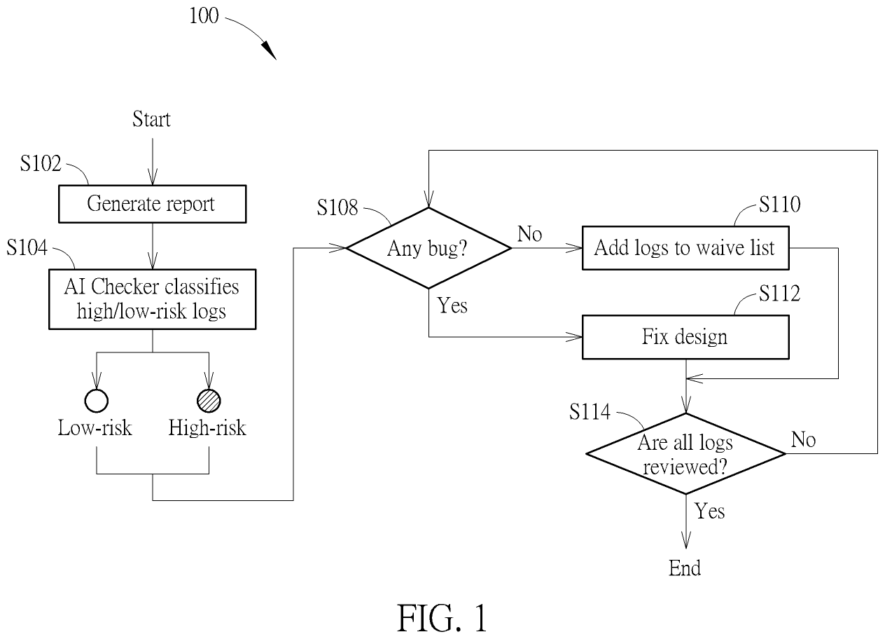

FIG. 1 is a flowchart of a violation checking method 100 using a machine learning model according to an embodiment of the present invention. The violation checking method 100 includes the following steps:

Step S102: generate a report including violation logs;

Step S104: classify the violation logs into high-risk logs and low-risk logs by a machine learning model;

Step S108: review a violation log to check if there is any bug in the violation log; if yes, go to step S112; else, go to step S110;

Step S110: add the violation log to a waive list; go to step S114;

Step S112: fix the design to remove the bugs;

Step S114: check if all violation logs are reviewed; if yes, end the process; else, go to step S108.

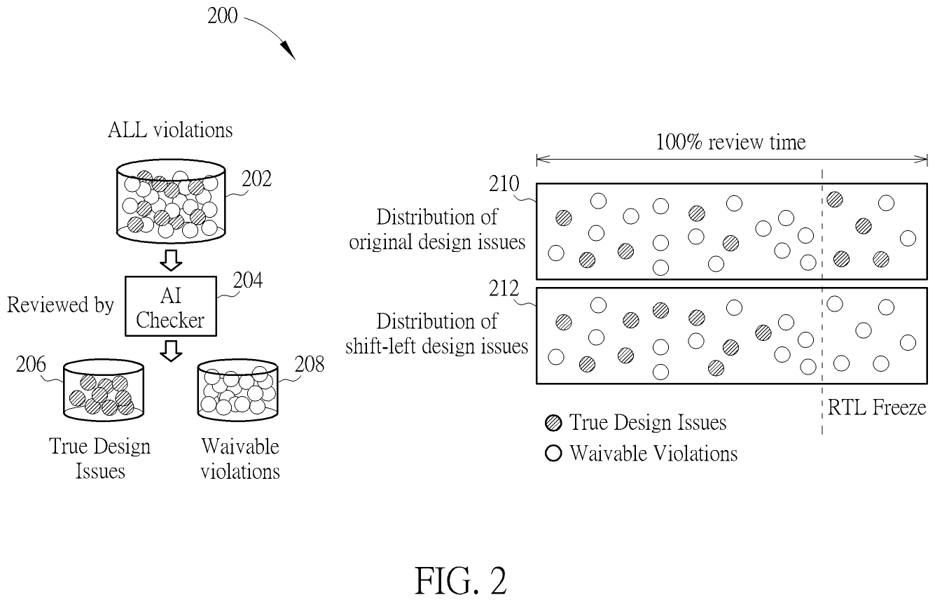

In step S102, a report with the violation logs is generated based on design. In step S104, the violation logs are classified into the high-risk logs and the low-risk logs by using the machine learning model as a classifier. The high-risk logs are more likely to have bugs and the low-risk logs are more likely to generate false alarms. Because the violation logs are composed of text and the words usually represent certain physical characteristics, the machine learning model is suitable to learn how to identify high-risk logs and low-risk logs from historical violation data. In an embodiment, in the training stage, the machine learning model is implemented to learn an Artificial Intelligence (AI) Checker that inherits and integrates the experiences of design domain experts across time and various design architectures. In the inference stage, the AI Checker is implemented to classify violations into waivable or high-risk violations to reduce false alarm violations. The validated labels of inspected violations can then be used for incremental learning. Experiments show the model can discover true design issues in predicted high-risk violations and the number of total violations can be reduced up to 50% to achieve shift left of design issues (as shown in FIG. 2).

In step S108, a high-risk log or a low-risk log is reviewed to check if the review log has any bug. If a bug is identified in step S108, go to step S112. If no bug is identified in step S108, go to step S110. In step S110, the violation log without bugs is added to a waive list to ignore the violation log. In step S112, the design with bugs related to the violation log is fixed. In step S114, check if all violation logs are reviewed. If all violation logs have been reviewed, end the process. If there are remaining violation logs not reviewed yet, go to step S108 to check if the next violation log has any bug. In the violation checking method 100, the high-risk logs are reviewed before the low-risk logs. In this way, most bugs can be fixed before the register transfer level (RTL) freezes so as to save reviewing time because fixing bugs would be more time consuming after register transfer level (RTL) freezes.

FIG. 2 is an architecture 200 of a violation checking method using a machine learning model according to an embodiment of the present invention. At first, all violation logs 202 are generated by a tool. Secondly, an artificial intelligence (AI) checker classifies the violation logs into high-risk logs 206 and low-risk logs 208. The high-risk logs 206 are violation logs more likely with true design issues. The low-risk logs 208 are violation logs more likely with waivable violations.

In the prior art, a schedule of review process 210 is drawn in FIG. 2. Some of the high-risk logs 206 with true design issues are distributed before the register transfer level (RTL) freezes and some of the high-risk logs 206 with true design issues are distributed after the register transfer level (RTL) freezes. After the register transfer level (RTL) freezes, the high-risk logs with true design issues are checked and fixed with a large amount of time.

In an embodiment of the present invention, a schedule of review process 212 is drawn in FIG. 2. All of the high-risk logs 206 with true design issues are distributed before the register transfer level (RTL) freezes and all of the violation logs 202 after the register transfer level (RTL) freezes are low-risk logs with waivable violations. The schedule of review process 212 works according to the classification of high-risk logs and low-risk logs using the machine learning model of the present embodiment.

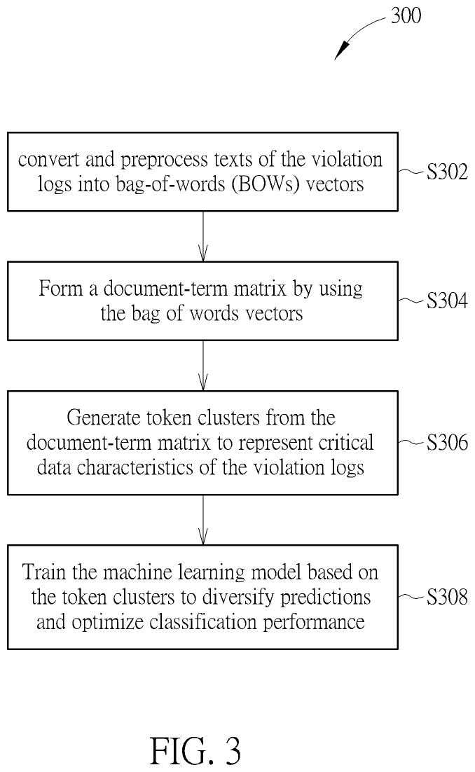

FIG. 3 is a flowchart of a machine learning method 300 used in the violation checking method 100 according to an embodiment of the present invention. The machine learning method 300 includes the following steps:

Step S302: convert and preprocess texts of the violation logs into bag-of-words (BOWs) vectors;

Step S304: form a document-term matrix by using the bag-of-words vectors;

Step S306: generate token clusters from the document-term matrix to represent critical data characteristics of the violation logs;

Step S308: train the machine learning model based on the token clusters to diversify predictions and optimize classification performance.

In step S302, the texts of the violation logs are converted and preprocessed into bag-of-words (BOWs) vectors. Bag-of-words (BOWs) is a representation of text that describes the occurrence of words within a document. It is used to encode each violation log. To construct BoW vectors, a vocabulary of known tokens is collected and token occurrence is measured for each violation log. The preprocessing method includes normalizing and standardizing the bag-of-words (BOWs) vectors. In step S304, the document-term matrix for training the machine learning models is formed by using the bag-of-words (BOWs) vectors. In step S306, token clusters are generated from the document-term matrix to represent critical data characteristics of the violation logs. In step S308, the machine learning model is trained based on the token clusters to diversify predictions and optimize classification performance.

Step S306 is optional. If step S306 is omitted, then step S308 becomes the machine learning model is trained based on the document-term matrix to diversify predictions and optimize classification performance. In step S308, the machine learning model can be an ensemble machine learning model, an extreme gradient boosting (XGBoost) model, a decision tree model, or a deep neural network (DNN) model. The machine learning model can be trained by using an optimizer such as adaptive moment (Adam), adaptive gradient descent (Adagrad), or stochastic gradient descent (SGD).

In conclusion, the embodiment of the present invention classifies the violation logs into the high-risk logs and the low-risk logs, and reschedules the violation logs according to the classification by using the machine learning model. By doing so, the violation logs with true design issues can be fixed before the register transfer level (RTL) freezes, thus reducing the time to fix the design.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A violation checking method comprising:
generating a violation log report for a design;
classifying violation logs in the violation log report into high-risk logs and low-risk logs by a machine learning model;
reviewing the high-risk logs; and
modifying the design if at least one bug is identified in the high-risk logs.

2. The method of claim 1 further comprising:
after modifying the design, reviewing the low-risk logs.

3. The method of claim 1 further comprising:
modifying the design if at least one bug is identified in the low-risk logs.

4. The method of claim 1, further comprising:
converting and preprocessing texts of the violation logs into bag-of-words (BOWs) vectors;
forming a document-term matrix by using the bag-of-words vectors; and
training the machine learning model based on the document-term matrix to diversify predictions and optimize classification performance.

5. The method of claim 4, wherein converting and preprocessing the texts of the violation logs into the bag-of-words (BOWs) vectors comprises normalizing and standardizing the bag-of-words (BOWs) vectors.

6. The method of claim 4, wherein training the machine learning model based on the document-term matrix to diversify the predictions and optimize the classification performance is training an ensemble machine learning model based on the document-term matrix to diversify the predictions and optimize the classification performance.

7. The method of claim 4, wherein training the machine learning model based on the document-term matrix to diversify the predictions and optimize the classification performance is training the machine learning model based on the document-term matrix by a optimizer of adaptive moment (Adam), adaptive gradient descent (Adagrad), or stochastic gradient descent (SGD) to diversify the predictions and optimize the classification performance.

8. The method of claim 1, wherein the machine learning model is an extreme gradient boosting (XGBoost) model, a decision tree model, or a deep neural network (DNN) model.

9. The method of claim 1, further comprising:
converting and preprocessing texts of the violation logs into bag-of-words (BOWs) vectors;
forming a document-term matrix by using the bag-of-words vectors;
generating token clusters from the document-term matrix to represent critical data characteristics of the violation logs; and
training the machine learning model based on the token clusters to diversify predictions and optimize classification performance.

10. The method of claim 9, wherein converting and preprocessing the texts of the violation logs into the bag-of-words (BOWs) vectors comprises normalizing and standardizing the bag-of-words (BOWs) vectors.

11. The method of claim 9, wherein training the machine learning model based on the token clusters to diversify the predictions and optimize the classification performance is training an ensemble machine learning model based on the token clusters to diversify the predictions and optimize the classification performance.

12. The method of claim 9, wherein training the machine learning model based on the token clusters to diversify the predictions and optimize the classification performance is training the machine learning model based on the token clusters by a optimizer of adaptive moment (Adam), adaptive gradient descent (Adagrad), or stochastic gradient descent (SGD) to diversify the predictions and optimize the classification performance.

13. The method of claim 1, further comprising:
adding violation logs without bugs to a waive list.

14. A violation checking method comprising:
generating a violation log report for a design;
classifying violation logs in the violation log report into high-risk logs and low-risk logs by a machine learning model;
reviewing the high-risk logs;
after reviewing the high-risk logs, reviewing the low-risk logs; and
modifying the design if at least one bug is identified in the low-risk logs.

15. The method of claim 14, further comprising:
converting and preprocessing texts of the violation logs into bag-of-words (BOWs) vectors;
forming a document-term matrix by using the bag-of-words vectors; and
training the machine learning model based on the document-term matrix to diversify predictions and optimize classification performance.

16. The method of claim 15, wherein converting and preprocessing the texts of the violation logs into the bag-of-words (BOWs) vectors comprises normalizing and standardizing the bag-of-words (BOWs) vectors.

17. The method of claim 15, wherein training the machine learning model based on the document-term matrix to diversify the predictions and optimize the classification performance is training an ensemble machine learning model based on the document-term matrix to diversify the predictions and optimize the classification performance.

18. The method of claim 14, further comprising:
converting and preprocessing texts of the violation logs into bag-of-words (BOWs) vectors;
forming a document-term matrix by using the bag-of-words vectors;
generating token clusters from the document-term matrix to represent critical data characteristics of the violation logs; and
training the machine learning model based on the token clusters to diversify predictions and optimize classification performance.

19. The method of claim 18, wherein converting and preprocessing the texts of the violation logs into the bag-of-words (BOWs) vectors comprises normalizing and standardizing the bag-of-words (BOWs) vectors.

20. The method of claim 14, further comprising:
adding violation logs without bugs to a waive list.
